(19) United States
(12) Patent Application Publication
(10) Pub. No.: US 2010/0195393 A1
(43) Pub. Date: Aug. 5, 2010

(54) Data storage system with refresh in place

(75) Inventor: David Eggleston, San Jose, CA (US)

Correspondence Address: UNITY SEMICONDUCTOR CORPORATION, 255 SANTA ANA COURT, SUNNYVALE, CA, 94085-4511, US

(73) Assignee: UNITY SEMICONDUCTOR CORPORATION, Sunnyvale, CA (US)

(21) Appl. No.: 12/653,939

(22) Filed: Dec. 18, 2009

Related U.S. Application Data
(60) Provisional application No. 61/206,397, filed on Jan. 30, 2009.

(51) Int. Cl. G11C 16/06

(52) U.S. Cl. 365/185.09; 365/185.25; 365/185.08

(57) ABSTRACT

A data storage system for refreshing in place data stored in a non-volatile re-writeable memory is disclosed. Data from a location memory can be read into a temporary storage location; the data at the memory location can be erased; the read data error corrected if necessary; and then the read data can be programmed and rewritten back to the same memory location it was read from. One or more layers of the non-volatile re-writeable memory can be fabricated BEOL as two-terminal cross-point memory arrays that are fabricated over a substrate including active circuitry fabricated FEOL. A portion of the active circuitry can be electrically coupled with the one or more layers of two-terminal cross-point memory arrays to perform data operations on the arrays, such as refresh in place operations or a read operation that triggers a refresh in place operation. The arrays can include a plurality of two-terminal memory cells.

### FIELD OF THE INVENTION

The present invention relates generally to data storage technology. More specifically, the present invention relates to reduction of read disturbs in block and page data operations on non-volatile re-writeable memory.

### BACKGROUND

In non-volatile memory, a disturb is defined as the loss of stored data as a result of a data operation. Typically, data is stored at a single address or at multiple addresses such as a block containing several pages of data. Each address may include several bits of data (e.g., one or more bytes or words) with each bit of data being stored in a non-volatile memory cell. A typical disturb can result in one or more memory cells changing their stored data in response to a data operation (e.g., a read, write, program, or erase operation) applied the memory cell during the data operation or to an adjacent memory cell during a data operation to the adjacent memory cell. For example, the effects of a data disturb on a memory cell can occur after one read operation or can be cumulative over time such that the data stored in the memory cell gradually degrades over time after successive read operations to that memory cell. The degradation of the value of stored data can be explained as the gradual loss of some property of the memory cell over time, such as the case where data is stored as a plurality of conductivity profiles, where one conductivity profile is indicative of one logic state, and another conductivity profile is indicative of another logic state. For example, the erased state of the memory cell can be indicative of a logic “1” being stored in the memory cell and a programmed state can be indicative of a logic “0” being stored in the memory cell. The effect of a data disturb can result in an increase or a decrease (e.g., drift) in the conductivity values that represent the logic “1” or the logic “0”. As one example, if a resistance for the programmed state is approximately 1.0MΩ and the resistance of the erased state is approximately 100 kΩ, then the effects of a disturb can result in a reduction in the resistance value of the programmed state from ≈1.0MΩ to some lower value (e.g., 500 kΩ) and an increase in the resistance value for the erased state from ≈100 kΩ to some higher value (e.g., 300 kΩ).

In some memory devices, the value of the stored data is determined by placing a read voltage across the memory cell (e.g., a two-terminal memory cell) and sensing a current that flows through the memory cell while the read voltage is applied. A magnitude of the read current is indicative of the conductivity profile (e.g., the resistive state) of the data stored in the memory cell and therefore the value of data stored in the memory cell (e.g., a logic “1” or a logic “0”). The circuitry that senses the read current outputs a logic value based on the magnitude of the read current. Preferably, the difference in resistance values for the programmed and erased states is some large ratio (e.g., 1.0MΩ/100 kΩ=10) such that the signal to noise ratio (S/N) is higher when the ratio between the resistive states is higher. Preferably, the ratio is ≧10. More preferably, the ration is ≧100. As the values for the erased and/or programmed states drift due to the effects of disturb, the S/N ratio is affected and the sense circuitry may not be able to output reliable data. Consequently, the effects of disturbs can result in corrupted data.

In data storage systems that incorporate non-volatile memory in which data operations (e.g., read, write, program, erase) can be implemented in large bundles of data such as sectors, blocks, and pages, a large number of memory cells are affected by block and/or page data operations, such as reads, for example. As one example, FLASH memory requires that data be erased using a block erase operation that generally sets the state of all memory cells in the block to the erased state of logic “1”. Therefore, left unabated, disturbs can create data reliability problems (e.g., corrupted data) in data storage systems using non-volatile memory. Conventional data storage systems can employ several techniques to correct disturbed bits, including: (1) using error checking and correcting (ECC) to detect and correct disturb bits; (2) rewriting corrected data to a new memory location based on a counter tracking data operations to a memory block that exceeds some predetermined value for the block (e.g., a count limit); and (3) rewriting corrected read data to a new memory location when the ECC needed to correct failed bits exceeds some predetermined value.

Reference is now made to FIG. 1A, where a conventional data storage system 100 includes a controller 130 (e.g., a memory controller) in communication 140 with a host (not shown) and in communication 121 with at least one non-volatile memory 120. The host can be a system such as computer, microprocessor, DSP, or some other type of system that performs data operations on memory, for example. Communications 140 and 121 can be bi-directional. Although not depicted, one skilled in the art will appreciate that additional signals and/or busses such as control signals, address busses, data busses, and the like can be included in the conventional data storage system 100. The controller 130 can include a buffer memory 131 (e.g., a RAM) for temporary storage of data and an ECC engine 135 electrically coupled 138 with the buffer 131 and operative to perform error detection and correction on data read from memory 120. The memory 120 can include data stored as a large group of data such as a block, a sector, or one or more pages of data. Data 108 includes user data 110 and ECC data 112, where “X” represent failing data (e.g., corrupted read disturb data) that may require correction by ECC engine 135. Here, the ECC data 112 is part of the data storage overhead required for data 108.

The host, or some other system, commands a data operation (e.g., a read operation) operative to trigger the controller 130 to read 121 a sector or page of data from memory 120. The read data can be temporarily stored in the buffer memory 131 so that the ECC engine 135 can operate on the sector or page of data stored in the buffer memory 131 to determine which if any bits are failed bits requiring correction. Upon detection of failed bits, the ECC engine 135 generates syndromes 137 that are communicated 139 to the buffer 131 to correct the failed bits and the corrected read data is transmitted 140 to the host system. The failed bit can represent bits having nominal logic values that have been weakened by data disturbs, such that a nominal value for an erased state has become a weak erased state and/or a nominal value for a programmed state has become a weak programmed state. It should be noted that in the conventional data storage system 100, the ECC engine 135 detects the weak states, but does not correct the failed bits X in the memory 120. Instead, the ECC engine 135 corrects the failed bits and then passes the corrected data 140 to the requesting host system. Consequently, the data 108 still contains the failed bits X and each read of the data 108 will require correction by ECC engine 135.

Turning now to FIG. 1B, another conventional data storage system 150 includes at least one non-volatile memory 170 and a controller 160. Data is stored in memory 170 as a plurality of blocks such as blocks 171-175. Typical block sizes can be from about 32 pages per block to about 256 pages per block. Page sizes are typically 2 k bytes to 8 k bytes. The current trend is for increased page sizes in excess of 8 k bytes. A block of data 172 to be read during a read operation is denoted as block D and may include several pages of data (not shown). Controller 160 includes buffer memory 161, block counters 162, and ECC engine 165. Upon receiving a command 164 for a data operation (e.g., a read operation) on block D, the controller 160 reads 155 data from block D into buffer memory 161. Block counter 162 is in electrical communication 152 with memory 170 and maintains a count of the number of data operations (e.g., to the various data blocks in the memory 170, including a count C_{D} for the number of data operations to block D (e.g., the read 155). At the time of the read 155, if the count C_{D} exceeds some predetermined number, then block counters 170 signals 166 the controller 160 that the data being read 155 from block D requires correction by ECC engine 165. The actual number the count C_{D} must exceed to trigger the signal 166 will be application dependent and can be determined using several methods. As one example, the memory 170 can be characterized during fabrication and/or testing to determine empirically how many data operations can be performed on the memory 170 before bit failures start to occur. For example, if the number of data operations exceeds approximately 50 k operations, then block counters 162 can be configured to trigger signal 166 when the count C_{D} reaches 50 k counts. The data operations that can increase the count C_{D} for block D need not be specific data operations to block D. Data operations to adjacent memory blocks 171 and 173 as denoted by arrows a1 and a2 can result in disturbs to bits in block D. Accordingly, the scheme for incrementing the count C_{D} for block D can include counts of data operations to adjacent memory blocks.

Assuming for purposes of discussion that the count C_{D}≧50 k counts, then the ECC engine 165 corrects the read data in buffer memory 161 (e.g., a RAM), generates syndromes 167, and corrects 169 failed bits X in buffer memory 161. Subsequently, the controller 160 rewrites 151 the corrected data to a new location in the memory 170. Here, the new location is a new block of data 175 denoted as D_{NEW}. The corrected data from block D that is temporarily stored in buffer memory 161 is refreshed by writing 157 the corrected data to block D_{NEW}. In response to the count C_{D} exceeding its count limit, blocks counter 162 can reset the counter for count C_{D} block D.

After the data has been refreshed, the controller 160 or the host can be configured to determine what to do with block 172 in memory 170, which is now denoted as D_{OLD}. Block D_{OLD} can be marked as a dirty block to be recovered or reclaimed (e.g., by erasing the data in all the pages of block D_{OLD}). On the other hand, block D_{OLD} can be marked as permanently bad and removed (e.g., tossed) from the population of blocks in memory 170. A look-up table, dedicated registers, a memory, or some other form of data storage can be used to log bad blocks in memory 170 and to prevent data operations to those blocks. If the data operation to block D was a read operation, after correction of failed bits by ECC engine 165, the controller can optionally output corrected data 163 to the requesting host system. The operations of refreshing the data to block D_{NEW} and transmitting the corrected data 163 to the host can occur in parallel or substantially simultaneously. Although a block D of memory is depicted as being read, the actual reading and refreshing of the data in block D can occur one page at a time until all of the pages in block D have been corrected and rewritten to block D_{NEW}.

Moving on to FIG. 1C, yet another conventional data storage system 180 includes memory 170 and controller 190. The controller 190 includes a buffer memory 191 electrically coupled (198, 199) with an ECC engine 195. Unlike the system 150, the controller 190 does not include a block counter. A data operation command 194 (e.g., a read operation) is received by controller 190. The controller 190 reads a page of data from block D of memory 170 into buffer memory 191. ECC engine 195 error checks the page data for failed bits X, and if necessary corrects the failed bits. Here, during the error checking process, ECC engine 195 is configured to generate a signal 196 based on some predetermined value for the number of acceptable errors in the page or pages read from block D. If the predetermined value is exceeded, syndromes 197 are generated and communicated 199 to buffer memory 191. Bit errors in excess of the predetermined value can be indicative of bits that have been subjected to too many disturb events and are therefore corrupted. After the ECC engine 195 has operated on the failed bits X, the corrected data 193 can be transmitted to the requesting host system. Furthermore, as described above, activation of the signal 196 can result in the data in block D being refreshed by rewriting 187 the corrected data to a new block 171 in memory 170 denoted as D_{NEW}. If the predetermined value is not exceed, then the syndromes 197 can be generated to correct failed bits X and the data in block D can be transmitted to the requesting host system. As previously described, block D_{OLD} can be recovered or marked as bad and removed from the population of useable blocks in memory 170.

Disadvantages to the aforementioned conventional data storage systems 150 and 180 include: refreshing the data by rewriting it to a new block can create disturbs to blocks adjacent to the new block and/or the new block itself; refreshing requires storage overhead for blocks that are allocated to serve as new locations for the refreshed blocks; and refreshing can result in the old block being removed from the population of blocks in the memory thereby reducing storage capacity of the memory.

There are continuing efforts to improve data operations on non-volatile re-writable memory technologies.

### BRIEF DESCRIPTION OF THE DRAWINGS

The invention and its various embodiments are more fully appreciated in connection with the following detailed description taken in conjunction with the accompanying drawings, in which:

FIG. 1A depicts a conventional data storage system using a conventional ECC based operation to correct read data for transmission to a host system;

FIG. 1B depicts a conventional data storage system using a conventional counter based scheme to correct read data and to rewrite corrected data to a different memory location;

FIG. 1C depicts a conventional data storage system using a conventional ECC based scheme to correct read data and to rewrite corrected data to a different memory location;

FIG. 2A depicts a data storage system using a counter based operation to correct read data and to rewrite corrected data to the same memory location according to the present invention;

FIG. 2B depicts a data storage system using an ECC based operation to correct read data and to rewrite the corrected data to the same memory location according to the present invention;

FIG. 3A depicts a flow diagram for a method of reading data and programming the data to the same memory location in a data storage system according to the present invention;

FIG. 3B depicts a block diagram for reading data and programming the data to the same memory location in a data storage system according to the present invention;

FIG. 4A depicts an integrated circuit including memory cells disposed in a single memory array layer or in multiple memory array layers and fabricated over a substrate that includes active circuitry fabricated in a logic layer;

FIG. 4B depicts a cross-sectional view of an integrated circuit including a single layer of memory fabricated over a substrate including active circuitry fabricated in a logic layer;

FIG. 5 depicts a cross-sectional view of a die including BEOL memory layer(s) on top of a FEOL base layer; and

FIG. 6 depicts FEOL and BEOL processing on the same wafer to fabricate the die depicted in FIG. 5.

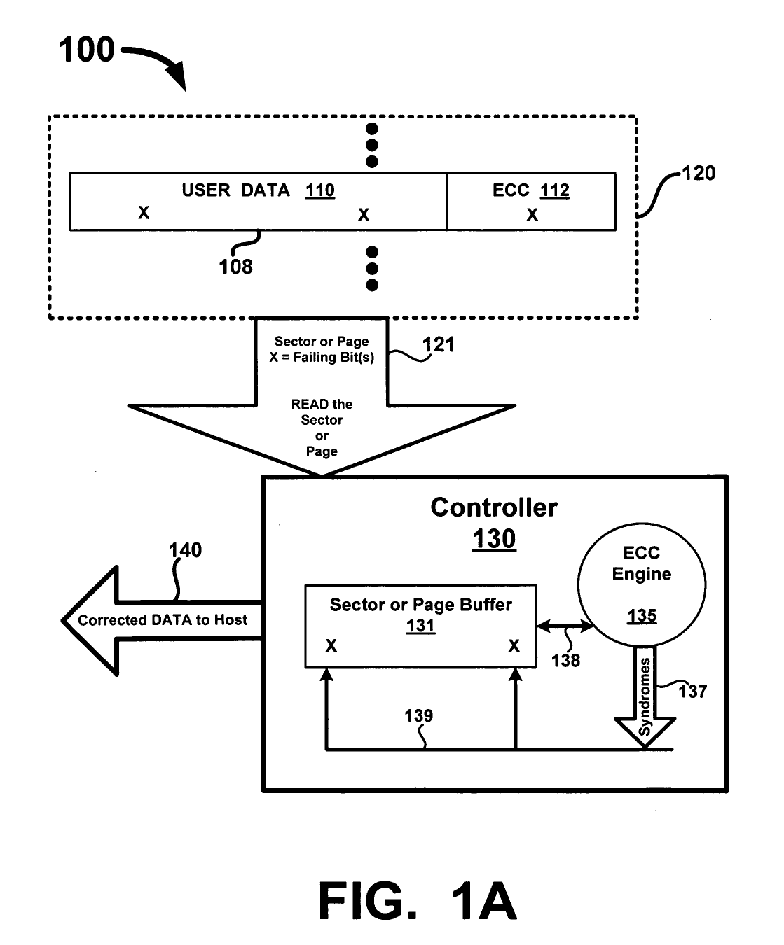

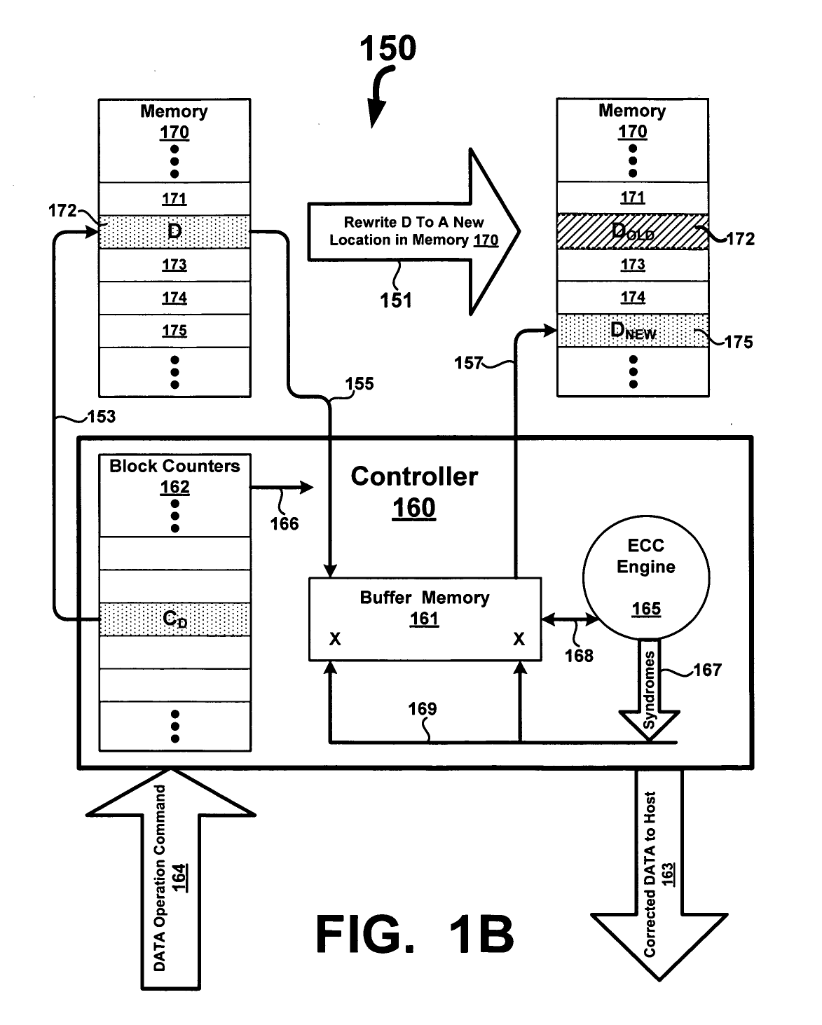

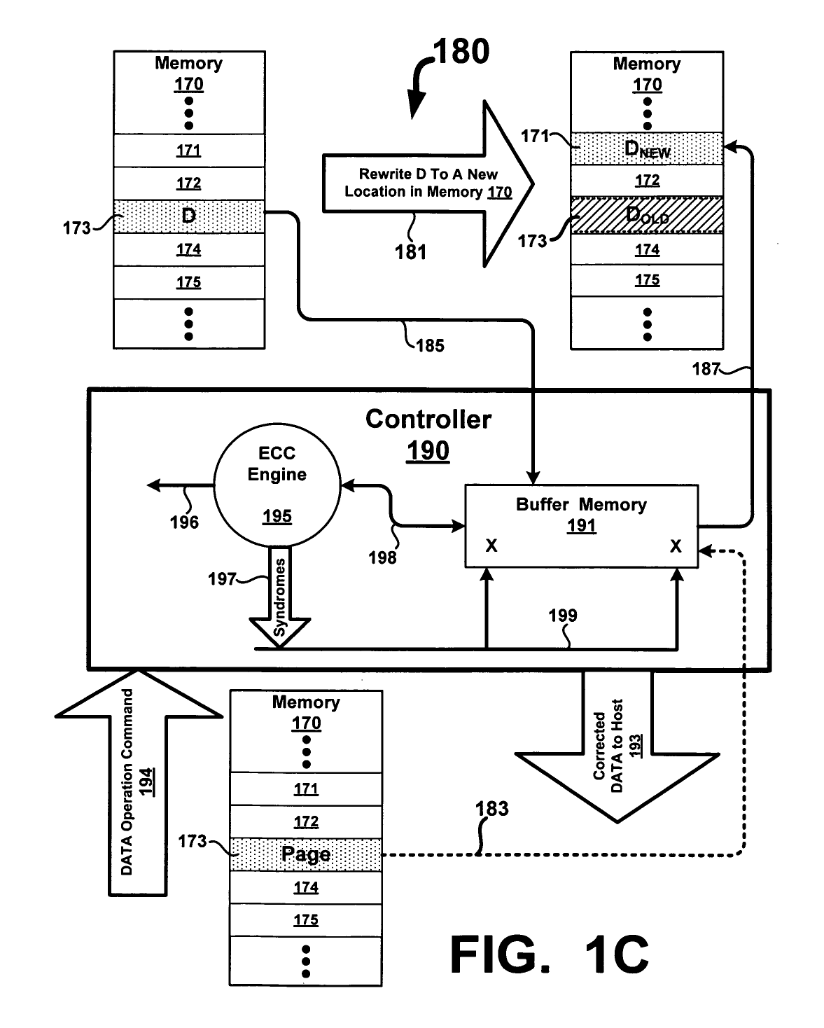

Although the above-described drawings depict various examples of the invention, the invention is not limited by the depicted examples. It is to be understood that, in the drawings, like reference numerals designate like structural elements. Also, it is understood that the drawings are not necessarily to scale.

### DETAILED DESCRIPTION

Various embodiments or examples of the invention may be implemented in numerous ways, including as a system, a process, an apparatus, or a series of program instructions on a computer readable medium such as a computer readable storage medium or a computer network where the program instructions are sent over optical, electronic, or wireless communication links. In general, operations of disclosed processes may be performed in an arbitrary order, unless otherwise provided in the claims.

A detailed description of one or more examples is provided below along with accompanying figures. The detailed description is provided in connection with such examples, but is not limited to any particular example. The scope is limited only by the claims, and numerous alternatives, modifications, and equivalents are encompassed. Numerous specific details are set forth in the following description in order to provide a thorough understanding. These details are provided as examples and the described techniques may be practiced according to the claims without some or all of the accompanying details. For clarity, technical material that is known in the technical fields related to the examples has not been described in detail to avoid unnecessarily obscuring the description.

There is an unmet need to perform the rewrite (i.e., refresh) of disturbed data in place, that is, to the same memory location, rather than rewriting the refreshed data to a new memory location. Other issues that effect reliability of non-volatile memory devices, such as the loss of data over time, often referred to as data retention, can be addressed by refreshing in place disturbed data. The refreshing of the data in place restores the conductivity profiles of failed bits to their nominal values. The goal of using refresh in place is to ensure the reliability of data storage systems without the extra time and hardware resources necessary to rewrite refreshed data to a new memory location. The refresh in place can be implemented with a command(s) and/or operation in the memory to be refreshed whereby the data is refreshed in place without the need to move the data to a new location in the memory being refreshed. The refresh in place can be applied to various data sizes such as bit(s), byte(s), word(s), page(s), and block(s). Depending on the data size selected for the refresh in place, the rewriting to the same location in memory includes rewriting data in the same address range as the original data. For example, if the data size is a block that includes 256 pages with a page size of 8 k bytes and the block has a beginning and/or ending address in the memory, then the refresh in place rewrites the data starting at the same beginning address for the block and may continue until the ending address of the block. All the data in the block can be refreshed in place (e.g., all of the pages) or only some of the data can be refreshed in place (e.g., only some of the pages).

New memory structures are possible using third dimensional memory arrays that include third dimensional two-terminal memory cells that may be arranged in a two-terminal, cross-point memory array as described in U.S. patent application Ser. No. 11/095,026, filed Mar. 30, 2005, entitled “Memory Using Mixed Valence Conductive Oxides,” and published as U.S. Pub. No. US 2006/0171200 A1, is incorporated herein by reference in its entirety and for all purposes. In at least some embodiments, a two-terminal memory cell can be configured to store data as a plurality of conductivity profiles and to change conductivity when exposed to an appropriate voltage drop across the two-terminals. The memory cell can include an electrolytic tunnel barrier and a mixed ionic-electronic conductor in some embodiments, as well as multiple mixed ionic-electronic conductors in other embodiments. A voltage drop across the electrolytic tunnel barrier can cause an electrical field within the mixed ionic-electronic conductor that is strong enough to move trivalent mobile ions out of the mixed ionic-electronic conductor, according to some embodiments.

In some embodiments, an electrolytic tunnel barrier and one or more mixed ionic-electronic conductor structures do not need to operate in a silicon substrate, and, therefore, can be fabricated above circuitry being used for other purposes. For example, a substrate (e.g., a silicon—Si wafer) can include active circuitry (e.g., CMOS circuitry) fabricated on the substrate as part of a front-end-of-the-line (FEOL) process. Examples of FEOL active circuitry includes but is not limited to all the circuitry required to perform data operations, including refresh in place, on the one or more layers of third dimension memory that are fabricated BEOL above the active circuitry in the substrate. After the FEOL process is completed, one or more layers of two-terminal cross-point memory arrays are fabricated over the active circuitry on the substrate as part of a back-end-of-the-line process (BEOL). The BEOL process includes fabricating the conductive array lines and the memory cells that are positioned at cross-points of conductive array lines (e.g., row and column conductive array lines). An interconnect structure (e.g., vias, thrus, plugs, damascene structures, and the like) may be used to electrically couple the active circuitry with the one or more layers of cross-point arrays. The interconnect structure can be fabricated FEOL. Further, a two-terminal memory cell can be arranged as a cross-point such that one terminal is electrically coupled with an X-direction line (or an “X-line”) and the other terminal is electrically coupled with a Y-direction line (or a “Y-line”). A third dimensional memory can include multiple memory cells vertically stacked upon one another, sometimes sharing X-direction and Y-direction lines in a layer of memory, and sometimes having isolated lines. When a first write voltage, VW1, is applied across the memory element (e.g., by applying ½ VW1 to the X-direction line and ½ −VW1 to the Y-direction line), the memory cell can switch to a low resistive state. When a second write voltage, VW2, is applied across the memory cell (e.g., by applying ½ VW2 to the X-direction line and ½ −VW2 to the Y-direction line), the memory cell can switch to a high resistive state. Memory cell using electrolytic tunnel barriers and mixed ionic-electronic conductors can have VW1 opposite in polarity from VW2.

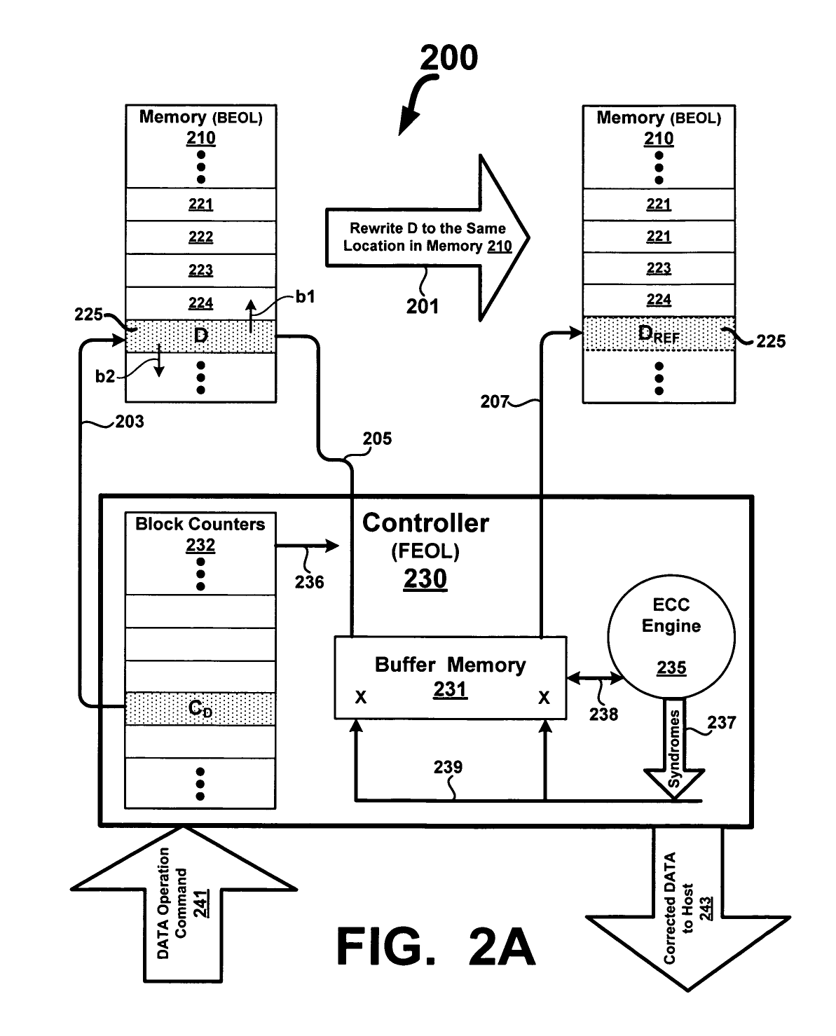

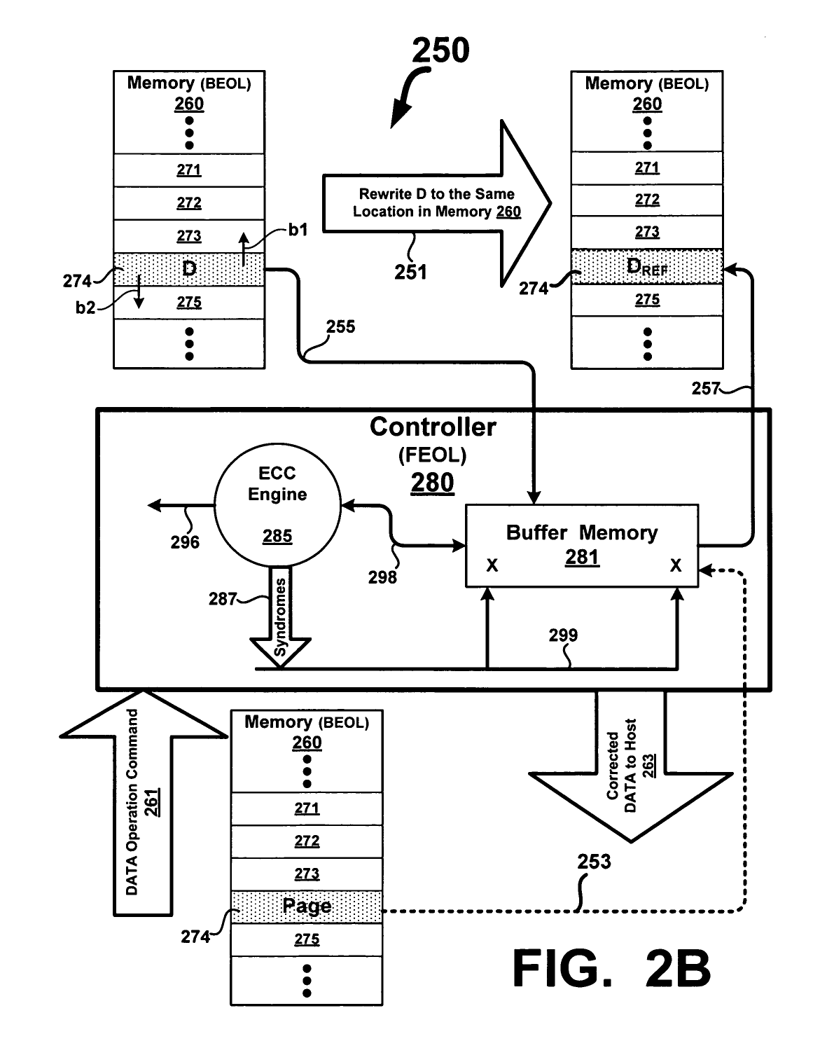

Reference is now made to FIG. 2A where a data storage system 200 includes at least one memory 210 and a controller 230 (e.g., a memory controller) in electrical communication with the at least one memory 210. As was described above, the controller 230 and other circuitry (not shown) necessary to perform data operations on the at least one memory 210 can be fabricated FEOL on a substrate (e.g., CMOS on a silicon wafer) and the at least one memory 210 (memory 210 hereinafter) can be fabricated BEOL in contact with and positioned directly above the substrate. The memory 210 can be a non-volatile two-terminal cross-point memory array that is fabricated BEOL. The memory 210 has data stored therein organized into a plurality of blocks (only five are depicted 221-225), with each block including a plurality of pages. The actual configuration for data storage in the memory will be application dependent and the configuration depicted is for purposes of explanation only. Furthermore the number of blocks, the number of pages in a block, and the size of the pages will be application dependent.

The controller 230 includes blocks counters 232, buffer memory 231, and ECC engine 235 electrically coupled with (237, 238, 239) the buffer memory 231. The controller 230 can be in electrical communication with a host system (not shown) and can be configured to receive data operation commands 241 and output corrected data 243 to the host system. In system 200, the refresh in place operation can be triggered by one or more events including but not limited to a specific refresh in place command received by the controller 230 (e.g., from a host system), a signal 236 from block counters 232, and a data operation (e.g., a read operation) on the memory 210, just to name a few. In FIG. 2A, block counters 232 maintains a count of data operations to blocks of data in memory 210. As depicted, block counters 232 is in communication 203 with memory 210 and maintains a count C_{D} of data operations on block 225 denoted as block D. For purposes of explanation, assume that the count C_{D} for block D has exceeded some predetermined limit (e.g., ≧60K counts) for data operations to a block. Block counters 232 activates a signal 236 and the controller 230 initiates a read of data 205 from block D into buffer memory 231 where the data is temporarily stored. Prior to writing the read data back to the same location (block D) in memory 210 the count C_{D} is indicative of the possibility the data has lost integrity and includes failed bit(s) X in one or more pages of block D. ECC engine 235 operates on the page data in buffer memory 231 and generates syndromes 237 to correct failed bits X. After the page data has been corrected, the controller 230 refreshes the corrected data to the same memory location for block D by rewriting 207 the corrected page data in buffer memory 231 to the same location in memory 210 now denoted as D_{REF} for a refreshed block 225 because the data from original block D has been refreshed in place to the same location. The page data temporarily stored in the buffer memory 231 can be transmitted 243 to a host system or some other system requiring or requesting the data from memory 210. The data can be transmitted 243 before, during, or after the refresh in place operation.

The refresh in place operation described above can be triggered by a specific refresh in place command communicated 241 to controller 230, or because the block count C_{D} has exceed the predetermined limit for data operations to a block. Here, when the block counters 232 activates the signal 236 based on the block count C_{D} being exceeded the refresh in place operation can be configured to proceed with the refresh in place only if the ECC engine 235 determines that there are failed bit(s) X to be corrected. If there are no failed bit(s) X to be corrected, then the rewrite 207 can be halted or the rewrite 207 can proceed and refresh the block anyway even though no failed bit(s) X were detected. When a block has its data refreshed, the counter for that block can be reset to some known count (e.g., 0).

Although data operations to the block D as logged by the block count C_{D} can be one method for determining when to refresh in place block D, data operations to adjacent blocks, as denoted by arrows b1 and b2, can also affect data in block D and cause disturbs. Therefore, in some applications the block count for adjacent blocks can be used individually or in combination with the block count C_{D} to determine if a refresh in place of block D is warranted due to block counts from one or both adjacent blocks, the block count C_{D}, or some combination of those block counts. For example, if the block count for adjacent block 273 is 44 k and the block count C_{D} is 50 k, then block counters 232 can activate the signal 236 even though block count C_{D} is not ≧60 k counts.

Referring now to FIG. 2B, a data storage system 250 includes a controller 280 that can be fabricated FEOL and at least one memory 260 that can be fabricated BEOL on top of the controller 280 and other circuitry required for data operations to the at least one memory 260 (memory 260 hereinafter). Controller 280 includes buffer memory 281 electrically coupled (287, 298, 299) with ECC engine 285. A data operation command 261 to controller 280 can initiate a read of a block 274 (denoted as block D) from memory 260. The data operation can be a read operation or a refresh in place operation, for example. Controller 280 reads 253 a page of data from block D into buffer memory 281. ECC engine 285 counts the number of failed bits X in the page of data read into buffer memory 281. If the count of failed bits exceeds some predetermined value or limit, then the ECC engine 285 activates a signal 296 that is communicated to the controller 280 and indicates that error correction is required on the data in buffer memory 281. Subsequently, ECC engine 285 generates syndromes 287 and writes corrected bits to buffer memory 281. If the data operation is a read, the corrected data can be transmitted 263 to a host system. Further, the activation of signal 296 is indicative of failed bits that can be caused by disturbs to the data in block D. Accordingly, the controller 280 rewrites 257 the corrected data in buffer memory 281 into the same memory location for block D (e.g., the same page is overwritten with corrected page data) denoted as D_{REF} for refreshed block 274. If the ECC engine 285 does not activate the signal 296, then the data in block D can be transmitted to the host system if the data operation is a read operation, or if not a read operation, then the refresh operation is cancelled and no rewrite of the data occurs. As noted above, data operations to adjacent blocks (b1, b2) can be the cause of disturbs to data in block D.

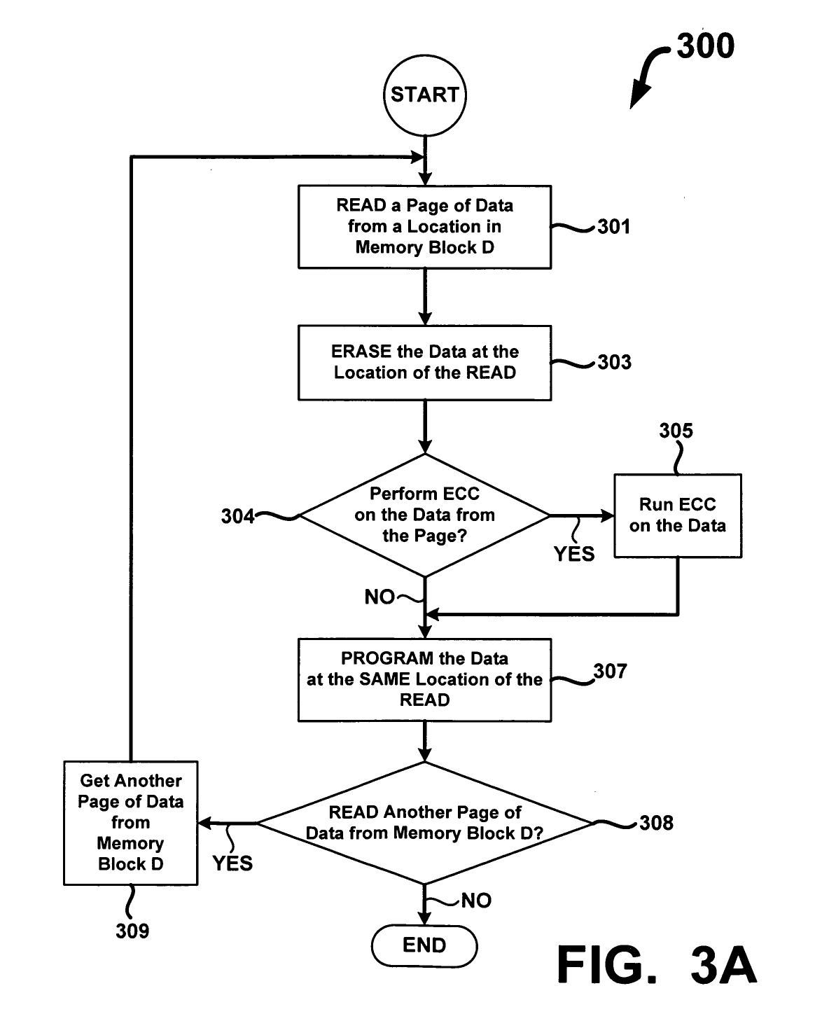

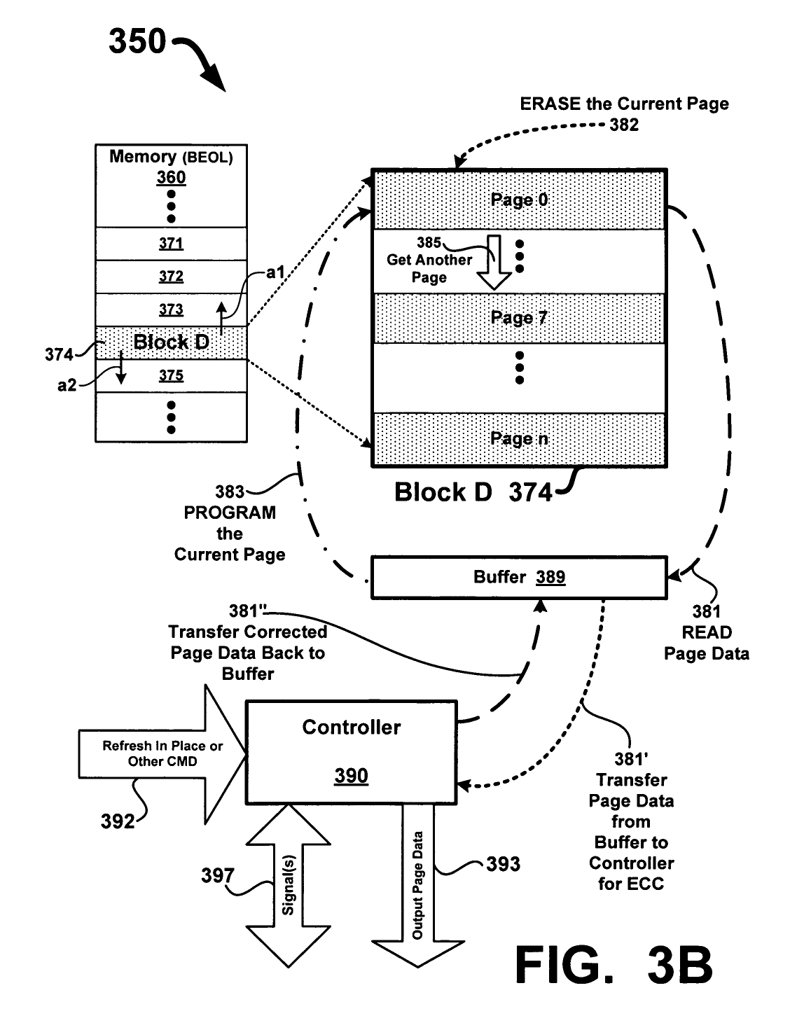

Attention is now directed to FIG. 3A where a method 300 for refreshing data in place includes at a stage 301 reading a page of data from a location in a block of memory. For example, the page data can be read into a random access memory (RAM) such as buffer memories 231 or 281. Although the method 300 depicts pages of data and blocks of memory, the read can be some other measure of data in the memory being read and is not limited to pages or blocks. At a stage 303 the data at the location in block D that was read at the stage 301 is erased (e.g., by setting all bits in the page to a logic “1”). As a result, the page in block D has all erased bits. At a stage 304 a determination is made as to whether ECC needs to be performed on the data read at the stage 301. As described above, ECC can be implemented if a block counter C_{D} for the block or quantum of data being read exceeds some predetermined limit or if the number of failed bits X exceeds some predetermined limit, for example. If the “YES” branch is taken, then at a stage 305 ECC is run on the data (e.g., in the buffer memory) and the method continues at a stage 307. On the other hand, if the “NO” branch is taken, then ECC is not run on the data and the method continues at a stage 307. At the stage 307, using the data in the buffer memory as a template, all bits in the erased page in block D that should be in the programmed state are programmed (e.g., set to a logic “0”). The program operation occurs at the same location the page of data was read from thereby refreshing in place the page of data in block D. At a stage 308, a determination is made as to whether or not to read another page of data from block D. If the “NO” branch is selected, then the method 300 terminates. Conversely, if the “YES” branch is selected, then at a stage 309 another page of data is retrieved from block D and the method 300 continues at the stage 301. Pages or some or quantum of data can be read from block D in a contiguous manner such that if a block contains 8 k pages, the first page can have a relative address of 0 in the block, the contiguous page can have a relative address of 1, and the last page can have a relative address of 8191. The contiguous approach to reading pages can be useful when it is desirable to refresh the entire block being operated on. On the other hand, pages can be read from the block in a non-contiguous manner such that a page at a relative address of 256 can be read first, a page at relative address 416 can be read second, and so on. The non-contiguous approach to reading pages can be useful when it is desirable to only refresh a specific page(s) in a block. A command from a host system can determine what type of refresh in place operation is to be performed with a plurality of commands directed to performing application specific refresh in place operations.

Reference is now made to FIG. 3B where a diagram 350 depicts various steps in the refresh in place operation on a memory 360 that is electrically coupled with a controller 390 configured to receive commands (e.g., a refresh in place command 392) from a host system and to output 393 page data to a system requesting data (e.g., a read command from a host system). The controller 390 can include an ECC engine for correcting failed bits and optionally a blocks counter, as was described above. Here, based on some action by the controller 390, such as receiving the refresh in place command 392, block 374 (denoted as block D) has a page of data (Page 0) read 381 into buffer 389. The buffer 389 can be included in the controller 390. The page of data that was read at 381 is transferred 381′ to controller 390 for ECC. The transfer at 381′ can be automatic, due to a signal from a blocks counter, due to excess failed bits, or some other indicator(s) of unreliable data in the page. After ECC has been performed, corrected page data is transferred back 381″ to buffer 389. The data in Page 0 is erased 382 to set all bits to a known value such as a logic “1”, for example. After the page data is erased 382, the corrected page data in buffer 389 is used to refresh the data in Page 0 by programming 383 bits in Page 0 that were initially in the programmed state prior to the erase 382 back to their programmed state by setting those bits to a logic “0”, for example. Based on the type of refresh in place operation, the controller 390 gets another page of data 385, such as Page 1 or some other page in block D. The refresh in place process continues until the entire block D has been refreshed (e.g., Page 0-Page n) or until a selected subset of the pages have been refreshed.

Nothing precludes the controller 390 from initiating the refresh in place operation on memory 360 absent a command from an external source such as a host system. For example, the controller 390 can be configured to monitor blocks in memory 360 and to initiate refresh in place operations on blocks in which data reliability is determined to be suspect (e.g., based on a blocks counter, data operations on adjacent blocks, etc.) or based on some algorithm (frequency of data operations requested by a host or lack of bus activity) or metric (such as passage of time).

In that the memory 360 can be randomly accessed for data operations, a granularity of data accessed during data operations on the memory 360 can include data that is smaller than a block or a page. For example, a read or write of a unit of data as small as a single bit of data or larger (e.g., a word, a byte, a nibble) can be performed. The unit of data need not be a standard unit such as a word, a byte, or a nibble, but can be a single bit, an odd number of bits, an even number of bits, etc. In some applications, one or more bits in a block, a page, a word, a byte, a nibble, or some other unit of data can be written or read and those bits need not be contiguous bits. For example, in a 32-bit word including bits 0-31, bits at positions 2, 6, 7, 15, and 29 in the 32-bit word can be directly accessed for a read or write operation. As another example, bytes or nibbles within a word can be read or written. Accordingly, the refresh in place operations described above can be performed on non-page or non-block data sizes.

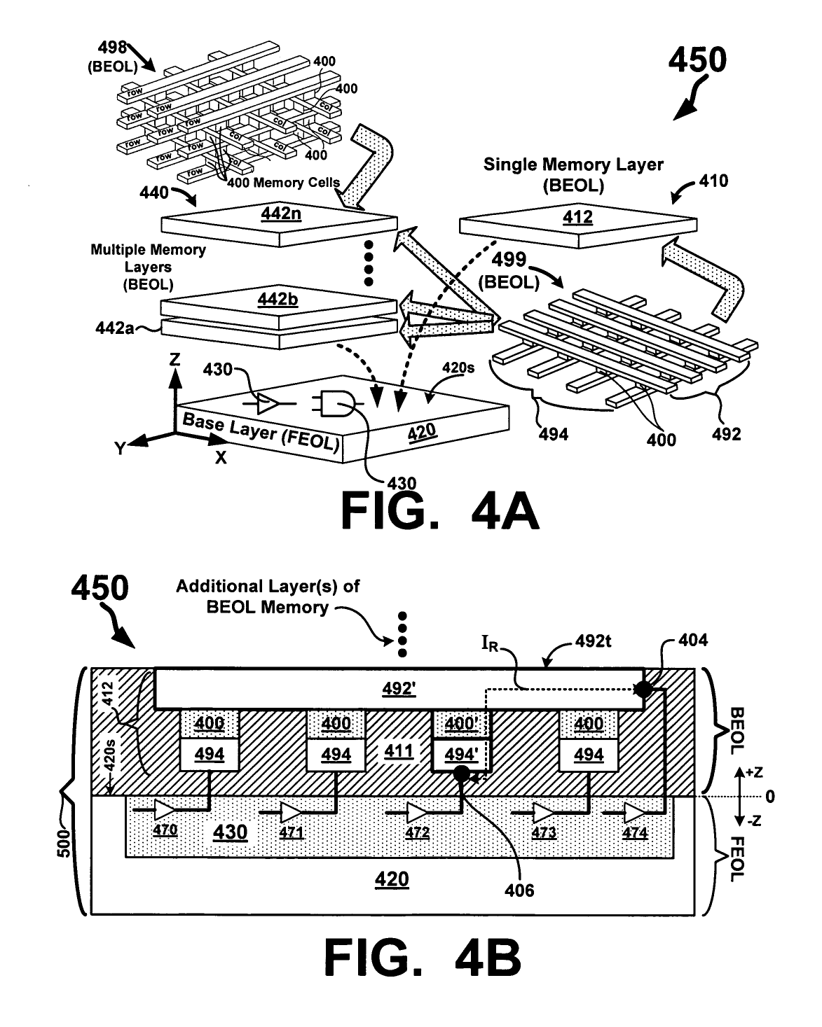

Turning now to FIG. 4A, an integrated circuit 450 can include non-volatile and re-writable memory cells 400 disposed in a single layer 410 or in multiple layers 440 of memory, according to various embodiments of the invention. In this example, integrated circuit 450 is shown to include either multiple layers 440 of memory (e.g., layers 442a, 442b, . . . 442n) or a single layer 410 of memory 412 formed on (e.g., fabricated above) a base layer 420 (e.g., a silicon wafer). In at least some embodiments, each layer of memory (412, or 442a, 442b, . . . 442n) can include a two-terminal cross-point array 499 having conductive array lines (492, 494) arranged in different directions (e.g., substantially orthogonal to one another) to access memory cells 400 (e.g., two-terminal memory cells). For example, conductors 492 can be X-direction array lines (e.g., row conductors) and conductors 494 can be Y-direction array lines (e.g., column conductors). The array 499 and the layers of memory 412, or 442a, 442b, . . . 442n can be fabricated back-end-of-the-line (BEOL) on top of the base layer 420. Base layer 420 can include a bulk semiconductor substrate upon which circuitry, such as memory access circuits (e.g., controllers, memory controllers, DMA circuits, μP, DSP, address decoders, drivers, sense amps, etc.) can be formed as part of a front-end-of-the-line (FEOL) fabrication process. The aforementioned controllers (230, 280, 390) can be fabricated on the substrate 420 FEOL and the aforementioned memories (210, 260, 360) can be fabricated BEOL on top of the substrate 420 and in electrical communication with the FEOL circuitry on the substrate 420. For example, base layer 420 may be a silicon (Si) substrate or some other semiconductor substrate or wafer upon which the active circuitry 430 is fabricated. The active circuitry 430 can include analog and digital circuits configured to perform data operations on the memory layer(s) that are fabricated above the base layer 420 and optionally configured to communicate with an external system(s) that electrically communicate with the active circuitry 430 in the base layer 420. An interconnect structure (not shown) including vias, plugs, thrus, and the like, may be used to electrically communicate signals from the active circuitry 430 to the conductive array lines (492, 494). Some or all of the circuitry depicted in FIGS. 2A, 2B, and 3B, can be fabricated on the base layer 420. The memory depicted in FIGS. 2A, 2B, and 3B can be disposed in a single layer (e.g., 412) or in multiple layers (e.g., 442a, 442b, . . . 442n). In some applications, the memory depicted in FIGS. 2A, 2B, and 3B can be disposed in one or more two-terminal cross-point arrays (e.g., 499) that are disposed in one layer of memory or disposed in multiple layers of memory as in a vertically stacked two-terminal cross-point arrays 498. In other applications, an address space for a single array (e.g., 499) can be partitioned (e.g., via hardware and/or software) to mimic two or more memories.

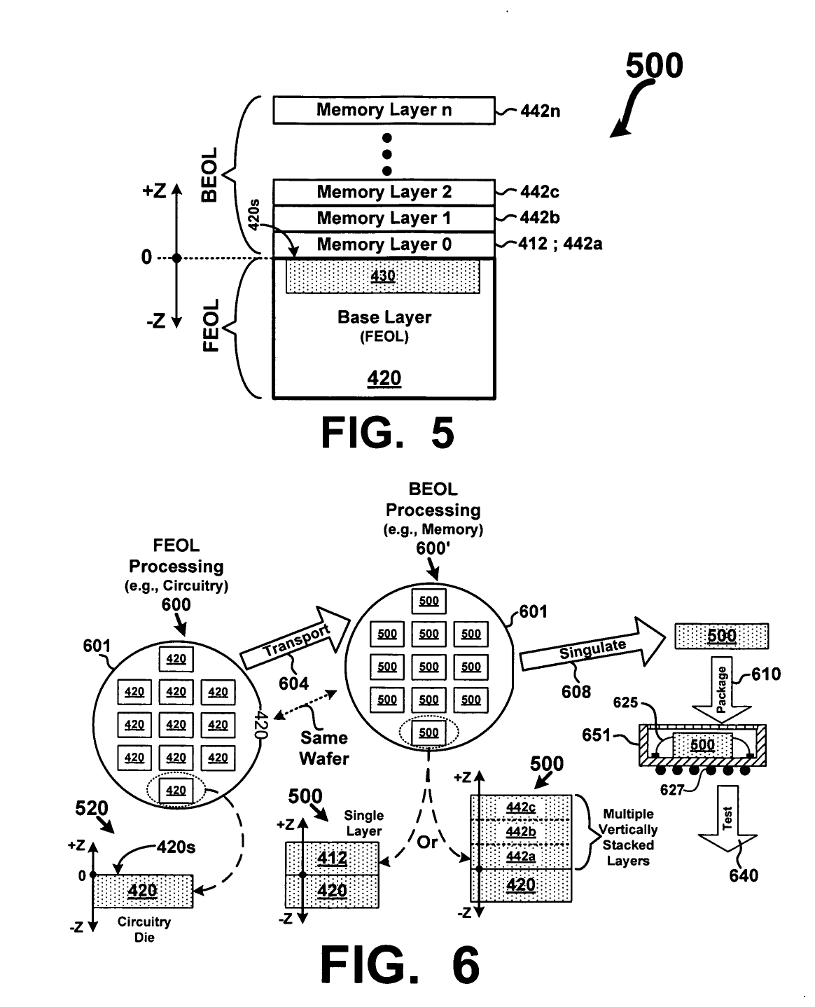

Reference is now made to FIG. 4B, where integrated circuit 450 includes the base layer 420 including active circuitry 430 fabricated FEOL on the base layer 420 and at least one layer of memory 412 (e.g., memories 210, 260, 360) fabricated BEOL above the base layer 420. As one example, the base layer 420 can be a silicon (Si) wafer and the active circuitry 430 can be microelectronic devices formed on the base layer 420 using a CMOS fabrication process. The memory cells 400 and their respective conductive array lines (492, 494) can be fabricated on top of the active circuitry 430 in the base layer 420. Those skilled in the art will appreciate that an inter-level interconnect structure (not shown) can electrically couple the conductive array lines (492, 494) with the active circuitry 430 which may include several metal layers. For example, vias can be used to electrically couple the conductive array lines (492, 494) with the active circuitry 430. The active circuitry 430 may include but is not limited to address decoders, sense amps, memory controllers (e.g., controllers 230, 280, 390), data buffers, direct memory access (DMA) circuits, voltage sources for generating the read and write voltages, DSPs, μPs, microcontrollers, registers, counters, and clocks, just to name a few. Active circuits 470-474 can be configured to apply the select voltage potentials (e.g., read and write voltage potentials) to selected conductive array lines (492′, 494′). Moreover, the active circuitry 430 may be coupled with the conductive array lines (492′, 494′) to sense a read current I_{R} from selected memory cells 400′ during a read operation and the sensed current can be processed by the active circuitry 430 to determine the conductivity profiles (e.g., the resistive state) of the selected memory cells 400′. In some applications, it may be desirable to prevent un-selected array lines (492, 494) from floating. The active circuits 430 can be configured to apply an un-select voltage potential (e.g., approximately a ground potential) to the un-selected array lines (492, 494). A dielectric material 411 (e.g., SiO₂) may be used where necessary to provide electrical insulation between elements of the integrated circuit 450. Here, active circuits 472 and 474 apply select voltages at nodes 406 and 404 to select memory cell 400′ for a data operation. Although only one selected cell is depicted, the block and page operations described above will operatively select a plurality of memory cells 400 during a data operation to the memory (e.g., 260, 360, 363). If multiple layers of memory are implemented in the integrated circuit 450, then those additional layers can be fabricated above the layer depicted in FIG. 4B, that is, above a surface 492t of array line 492′. In some applications using vertically stacked memory arrays, each layer of memory is electrically isolated (e.g., using a dielectric materials such as 411) from one another. In other applications, memory cells 400 in adjacent memory layers share one or more conductive array lines with a memory cell 400 in the layer above it, below it, or both above and below it (e.g., see 498 in FIG. 4A). Here, whether a single layer of memory or multiple layers of memory, the combined FEOL and BEOL portions form a unitary whole denoted as die 500 for an integrated circuit as will be explained in greater detail below in regards to FIGS. 5 and 6.

The various embodiments of the invention can be implemented in numerous ways, including as a system, a process, an apparatus, or a series of program instructions on a computer readable medium such as a computer readable storage medium or a computer network where the program instructions are sent over optical or electronic communication links. In general, the steps of disclosed processes can be performed in an arbitrary order, unless otherwise provided in the claims.

Moving now to FIG. 5, an integrated circuit 500 (e.g., a die from a wafer) is depicted in cross-sectional view and shows along the −Z axis the FEOL base layer 420 including circuitry 430 fabricated on the base layer 420. The integrated circuit 500 includes along the +Z axis, either a single layer of BEOL memory 412 fabricated in contact with and directly above the upper surface 420s of the base layer 420 and in electrical communication with the circuitry 430, or multiple layers of BEOL memory 442a-442n that are also fabricated in contact with and directly above the upper surface 420s of the base layer 420 and in electrical communication with the circuitry 430. The single layer 412 or the multiple layers 442a-442n are not fabricated separately and then physically and electrically coupled with the base layer 420, rather, they are grown directly on top of the base layer 420 using fabrications processes that are well understood in the microelectronics art. For example, microelectronics processes that are similar or identical to those used for fabricating CMOS devices can be used to fabricate the BEOL memory directly on top of the FEOL circuitry.

Referring now to FIG. 6, a wafer (e.g., a silicon—Si wafer) is depicted during two phases of fabrication (e.g., a silicon—Si wafer). During a FEOL phase, the wafer is denoted as 600 and during a subsequent BEOL phase the same wafer is denoted as 600′. During FEOL processing the wafer 600 includes a plurality of die 420 (e.g., base layer 420 depicted in FIGS. 4B and 5) that includes the circuitry 430 of FIG. 5 fabricated on the die 420. The die 420 is depicted in cross-sectional view below wafer 600. After FEOL processing is completed, the wafer 600 undergoes BEOL processing and is denoted as 600′. Optionally, the wafer 600 can be physically transported 604 to a different processing facility for the BEOL processing. The wafer 600′ undergoes BEOL processing to fabricate one or more layers of memory (412, or 442a-442c) directly on top of the upper surface 420s of the die 420 along the +Z axis as depicted in cross-sectional view below wafer 600′ where integrated circuit 500 includes a single layer or multiple vertically stacked layers of BEOL memory.

After BEOL processing is completed, the integrated circuit 500 (e.g., a unitary die including FEOL circuitry and BEOL memory) can be singulated 608 from the wafer 600′ and packaged 610 in a suitable IC package 651 using wire bonding 625 to electrically communicate signals with pins 627, for example. The IC 500 can be tested for good working die prior to being singulated 608 and/or can be tested 640 after packaging 610.

The foregoing description, for purposes of explanation, uses specific nomenclature to provide a thorough understanding of the invention. However, it will be apparent to one skilled in the art that specific details are not required in order to practice the invention. In fact, this description should not be read to limit any feature or aspect of the present invention to any embodiment; rather features and aspects of one embodiment can readily be interchanged with other embodiments. Notably, not every benefit described herein need be realized by each embodiment of the present invention; rather any specific embodiment can provide one or more of the advantages discussed above. In the claims, elements and/or operations do not imply any particular order of operation, unless explicitly stated in the claims. It is intended that the following claims and their equivalents define the scope of the invention.

What is claimed is:

1. A method of refreshing in place data in a re-writeable non-volatile memory comprising:
reading data from a first location in a memory;
storing the data in a temporary storage location;
erasing the data in the first location by writing all bits of the data to a first value;
checking the data in the temporary storage location for bit errors;
correcting the data in the temporary storage location if bit errors are found; and
programming only those bits in the first location that were not at the first value prior to the reading by writing those bits to a second value.

2. The method as set forth in claim 1, wherein the first value comprises a logic 1 and the second value comprises a logic 0.

3. The method as set forth in claim 1, wherein the data comprises a page of data read from a block of data in the memory.

4. The method as set forth in claim 1 and further comprising:
receiving a refresh in place command.

5. The method as set forth in claim 1, wherein the memory comprises at least one layer of a two-terminal cross-point memory array.

6. The method as set forth in claim 5, wherein the at least one layer of the two-terminal cross-point memory array is in contact with and is vertically stacked over a substrate that includes circuitry fabricated on the substrate and configured to perform data operations on the two-terminal cross-point memory array.

7. The method as set forth in claim 5, wherein the two-terminal cross-point memory array includes a plurality of two-terminal memory cells.

8. The method as set forth in claim 7, wherein the erasing comprises applying a first write voltage across the two terminals of at least one of the plurality of two-terminal memory cells.

9. The method as set forth in claim 7, wherein the programming comprises applying a second write voltage across the two terminals of at least one of the plurality of two-terminal memory cells.

10. The method as set forth in claim 7, wherein each two-terminal memory cell includes a two-terminal memory element electrically in series with the two-terminals of the two-terminal memory cell and each memory element is configured to store data as a plurality of conductivity profiles that can be non-destructively determined by applying a read voltage across its two terminals.

11. The method as set forth in claim 10, wherein the erasing comprises applying a first write voltage across the two terminals of the memory element.

12. The method as set forth in claim 10, wherein the programming comprises applying a second write voltage across the two terminals of the memory element.

13. The method as set forth in claim 1, wherein the temporary storage location comprises a random access memory.

14. The method as set forth in claim 1, wherein the memory does not require an erase operation prior to a write operation.

15. A method of refreshing in place data in a re-writeable non-volatile memory comprising:
reading data from a first location in a memory;
storing the data in a temporary storage location;
checking the data in the temporary storage location for bit errors;
correcting the data in the temporary storage location if bit errors are found; and
programming only those bits in the first location that were not at a first value prior to the reading by writing those bits to a second value.

16. The method as set forth in claim 15, wherein the memory comprises at least one layer of a two-terminal cross-point memory array that is in contact with and is vertically stacked over a substrate that includes circuitry fabricated on the substrate and configured to perform data operations on the two-terminal cross-point memory array.

17. The method as set forth in claim 16, wherein the two-terminal cross-point memory array includes a plurality of two-terminal memory cells.

18. The method as set forth in claim 17, wherein the programming comprises applying a first write voltage across the two terminals of at least one of the plurality of two-terminal memory cells.

19. The method of claim 17, and further comprising:
erasing the data in the first location by writing all bits of the data to the first value.

20. The method as set forth in claim 19, wherein the erasing comprises applying a second write voltage across the two terminals of at least one of the plurality of two-terminal memory cells.
